(19) United States
(12) Patent Application Publication
(10) Pub. No.: US 2005/0142734 A1
(43) Pub. Date: Jun. 30, 2005

(54) Isolation methods in semiconductor devices

(76) Inventor: Moon Jung Shin, Sungnam (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/024,636

(22) Filed: Dec. 28, 2004

(30) Foreign Application Priority Data
Dec. 30, 2003 (KR) 2003-0100537

(51) Int. Cl. H01L 21/8242

(52) U.S. Cl. 438/253

(57) ABSTRACT

Disclosed herein are isolation methods for use in semiconductor devices. One example method includes forming a hard mask layer by sequentially stacking a silicon oxide layer, a silicon nitride layer, and a thermal oxide layer on a semiconductor substrate, forming a hard mask layer pattern by patterning the hard mask layer to expose a surface of the semiconductor substrate corresponding to a field area, forming a spacer on each sidewall of the hard mask layer pattern by considering a per-side amount according to the pull-back target, forming a trench in the semiconductor substrate by removing the exposed surface of the semiconductor substrate, filling up the trench with an insulating layer, and removing the hard mask layer pattern and the spacer.

### TECHNICAL FIELD

The present disclosure relates to semiconductor devices and, more particularly, to isolation methods in semiconductor devices.

### BACKGROUND

Generally, a known device isolation method consists of the steps of growing a pad oxide layer for Si₃N₄ stress release, forming an oxide layer on the pad oxide layer, and forming an oxide layer as a mask layer for trench etch on the nitride layer. The known method also includes patterning the mask layer, performing the trench etch to form a trench, carrying out pull-back using H₃PO₄ strip to prevent divot and to secure an active width, growing an oxide layer on a field area again, and isolating an active area from the field area by carrying out CMP (chemical mechanical polishing) on the oxide layer.

FIG. 1 is a flowchart of a known method of forming a device isolation layer in a semiconductor device. FIGS. 2A to 2H are cross-sectional diagrams of a semiconductor device at various stages of the known method.

Referring to FIG. 1 and FIG. 2A, a silicon oxide layer 1 is formed as a buffer layer on a semiconductor substrate 10. A silicon nitride layer 2 is formed on the silicon oxide layer 1. A thermal oxide layer 3 is then formed on the silicon nitride layer 2 (S101).

Referring to FIG. 1 and FIG. 2B, photoresist is coated on the thermal oxide layer 3. Exposing and developing are carried out on the photoresist to form a photoresist pattern 4. The exposed thermal oxide layer 3, the nitride layer 2, and the oxide layer 1 are sequentially etched by dry etch using the photoresist pattern 4 as an etch mask (S102).

Referring to FIG. 1 and FIG. 2c, the photoresist pattern is removed by O₂ plasma ashing (S103).

Referring to FIG. 1 and FIG. 2D, an exposed surface of the silicon substrate 10 is etched by dry etch using the remaining thermal oxide and nitride layers 3 and 2 as an etch mask to form a trench 5 in the substrate 10 (S104).

Referring to FIG. 1 and FIG. 2E, pull-back is carried out on the trench 5 using an H₃PO₄ strip to form a recess 6 beneath the thermal oxide layer 3 (S105).

Referring to FIG. 1 and FIG. 2F, an oxide layer 7 for forming a field area is formed over the substrate including the trench 5 and the recess 6 (S106).

Referring to FIG. 1 and FIG. 2G, chemical mechanical polishing (CMP) is carried out on the oxide layer 7 in FIG. 2F until the silicon nitride layer 2 is exposed (S107).

Referring to FIG. 1 and FIG. 2H, by oxide wet etching and H₃PO₄ strip etching, an active area to a field height is tuned and the remaining silicon nitride and oxide layers 2 and 1 are removed (S108).

Hence, an active area and a field area are completed.

In the known pull-back process using dry etch, the pull-back effect can be backed up by spacer deposition and etch to solve various problems of wet etch.

However, the pull-back process by dry etch has difficulty in protecting the active area from being attacked in opening the mask. Accordingly, the active area may be degraded during etching.

### BRIEF DESCRIPTION OF THE DRAWINGS

FIG. 1 is a flowchart of a known method of forming a device isolation layer in a semiconductor device.

FIGS. 2A to 2H are cross-sectional diagrams of a semiconductor device at various stages of processing according to FIG. 1.

FIG. 3 is a flowchart of a disclosed example method of forming a device isolation layer in a semiconductor device.

FIGS. 4A to 4H are cross-sectional diagrams of a semiconductor device at various stages of processing according to FIG. 3.

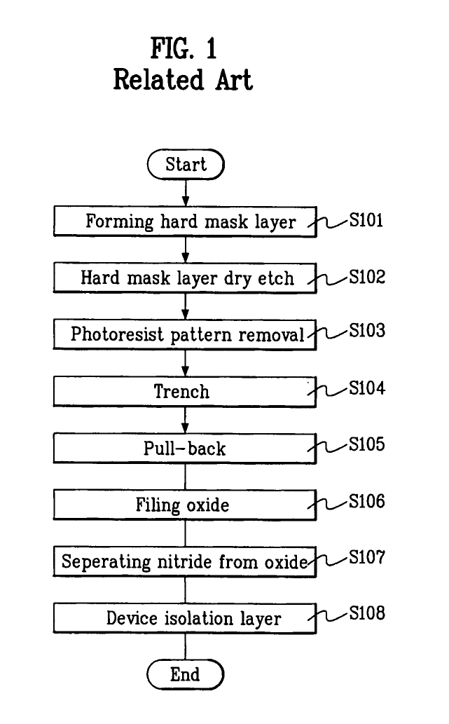

### DETAILED DESCRIPTION

As disclosed herein, isolation methods for use in semiconductors by which active attack is eliminated to secure a stable active area in case of employing pull-back by dry etch for trench isolation.

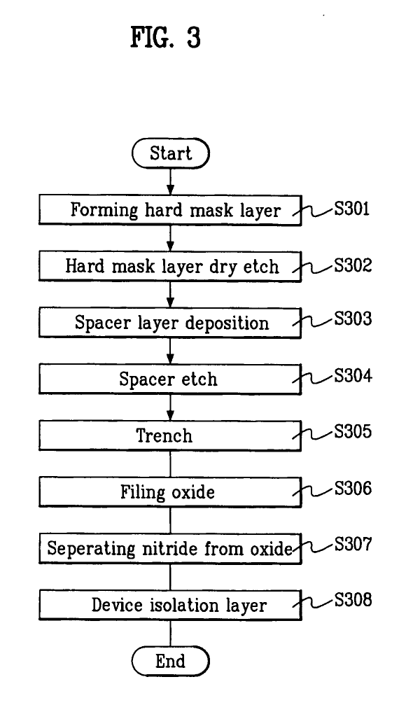

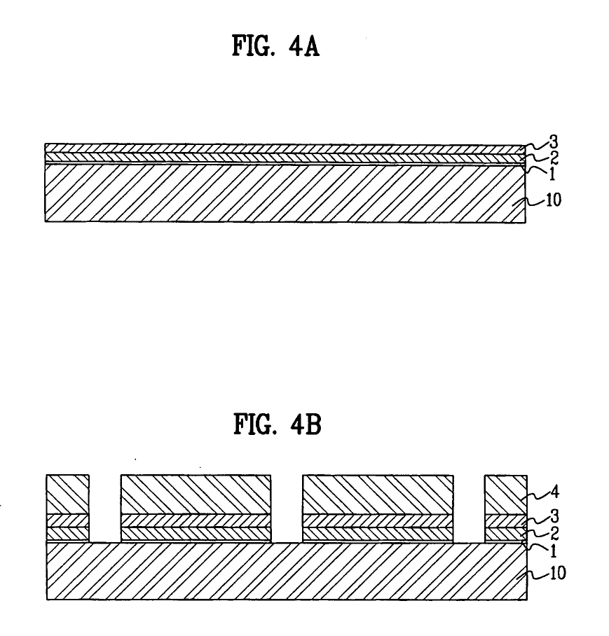

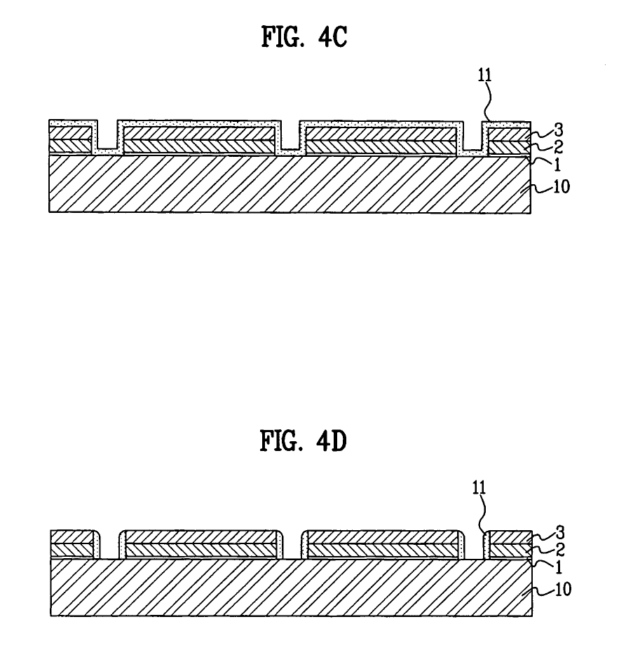

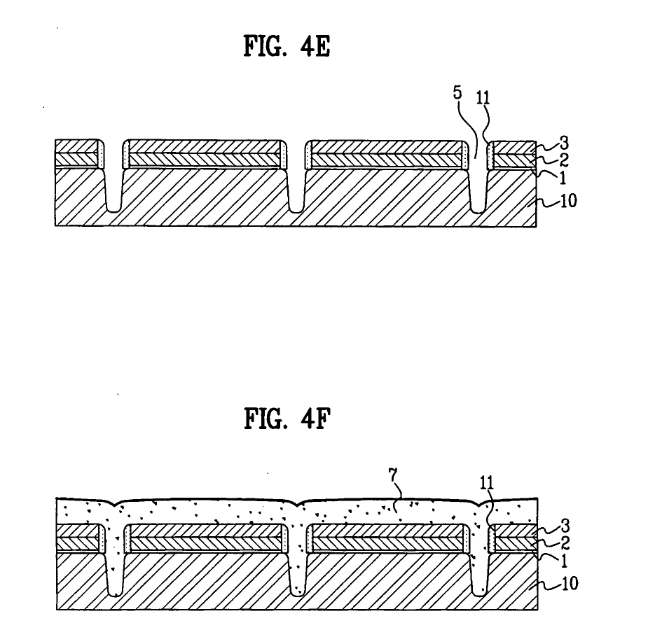

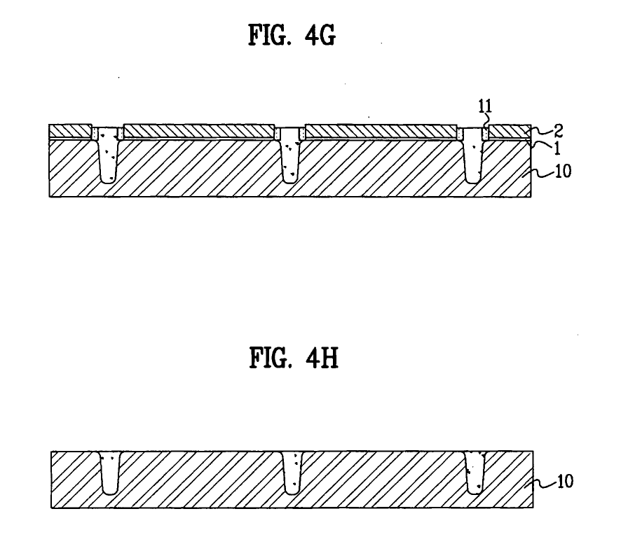

Referring to FIG. 3 and FIG. 4A, a silicon oxide layer 1 is formed as a buffer layer on a semiconductor substrate 10. A silicon nitride layer 2 is formed on the silicon oxide layer 1. A thermal oxide layer 3 is formed on the silicon nitride layer 2 (S301). In this example, the thermal oxide, silicon nitride, and silicon oxide layers 3, 2, and 1 are used as a hard mask for dry etch of the semiconductor substrate 10 of silicon.

Referring to FIG. 3 and FIG. 4B, photoresist is coated on the thermal oxide layer 3. Exposing and developing are carried out on the photoresist to form a photoresist pattern 4. The exposed hard mask thermal are then etched by dry etch using the photoresist pattern 4 as an etch mask (S302). In doing so, in order to get a specific device characteristic, the damage of the silicon substrate 10 may be prevented from etching the silicon oxide and nitride layers 1 and 2 of the hard mask. Hence, in etching the hard mask, a high etch selection ratio, which exceeds a rate for stopping the corresponding etch at the silicon oxide layer 1 for stress release, between the silicon oxide layer 1 and the silicon nitride layer 2 may be utilized. In one example, the high etch selection ratio between the silicon oxide layer 1 and the silicon nitride layer 2 is 10:1. As a condition for silicon nitride dry etch to get the corresponding high etch selection ratio, an HBr base gas is used at a temperature above 50° C.

Referring to FIG. 3 and FIG. 4c, the photoresist pattern is removed by O₂ plasma ashing/strip. A spacer layer 11 is then deposited over the substrate 10 including the remaining mask and an exposed surface of the substrate 10. In doing so, the spacer layer 11 is deposited to a thickness for compensation critical dimension and a pull-back target (S303).

Referring to the examples of FIG. 3 and FIG. 4D, the spacer layer 11 is etched back to form a spacer 11 remaining on each sidewall of the remaining hard mask (S304). In doing so, an etch amount needs to consider a per-side amount according to the pull-back target.

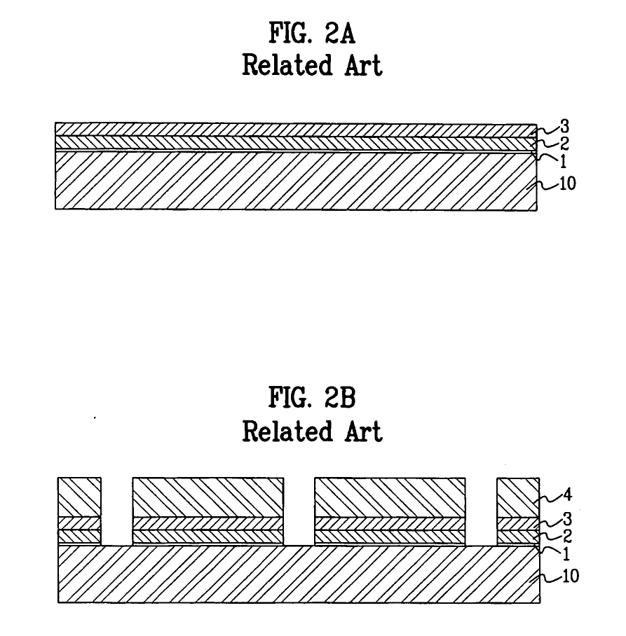

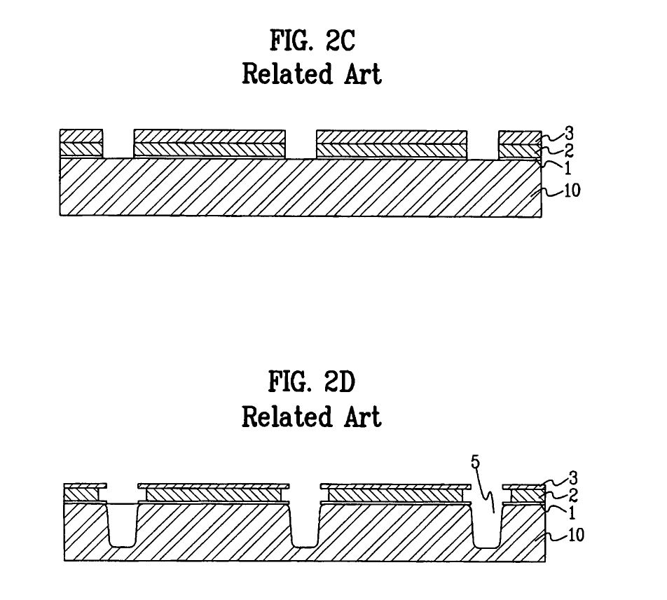

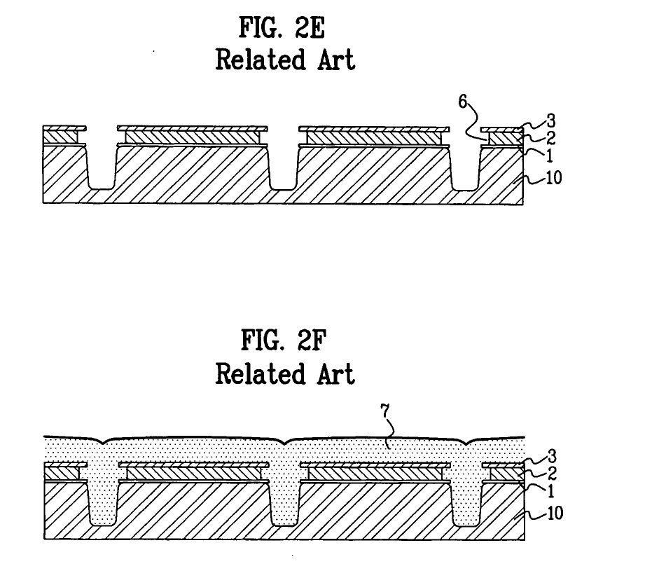

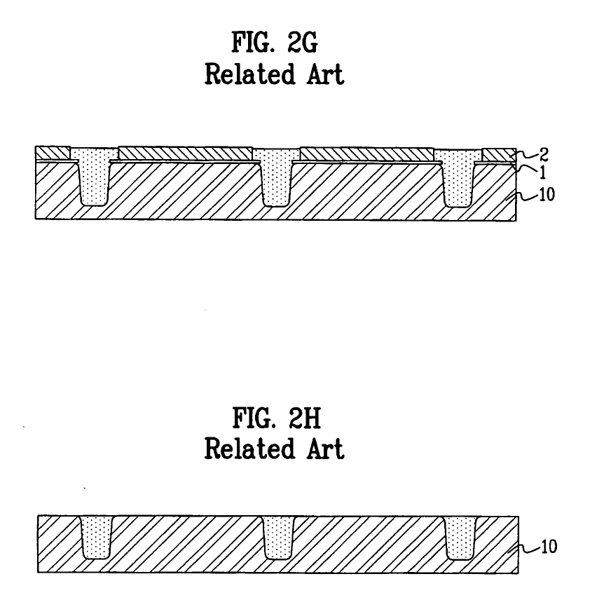

Referring to FIG. 3 and FIG. 4E, an exposed surface of the silicon substrate 10 is etched by dry etch using the remaining hard mask including the thermal oxide and nitride layers 3 and 2 and the spacer 11 as an etch mask to form a trench 5 in the substrate 10 (S305). Compared to the known trench forming in FIG. 2E, the trench forming disclosed herein secures the undercut of the silicon nitride layer 2 without using an additional process.

Referring to FIG. 3 and FIG. 4F, an oxide layer 7 for forming a field area is formed over the substrate including the trench 5 (S306). Referring to FIG. 3 and FIG. 4G, CMP is carried out on the oxide layer 7 in FIG. 2F until the silicon nitride layer 2 is exposed (S307).

Referring to FIG. 3 and FIG. 4H, by oxide wet and H₃PO₄ strip, an active area to a field height is tuned and the remaining silicon nitride and oxide layers 2 and 1 and the spacer 11 are removed (S308).

Hence, an active area and a field area are completed.

Accordingly, as disclosed herein, substrate damage is prevented from occurring in opening a mask using a high selectivity between a silicon nitride layer and a pad oxide layer and by which a stable active area is secured. Additionally, active area damage is prevented from occurring in dry pull-back in forming an active area of the semiconductor device.

According to one example, a disclosed method includes forming a hard mask layer by sequentially stacking a silicon oxide layer, a silicon nitride layer, and a thermal oxide layer on a semiconductor substrate, forming a hard mask layer pattern by patterning the hard mask layer to expose a surface of the semiconductor substrate corresponding to a field area, forming a spacer on each sidewall of the hard mask layer pattern by considering a per-side amount according to the pull-back target, forming a trench in the semiconductor substrate by removing the exposed surface of the semiconductor substrate, filling up the trench with an insulating layer, and removing the hard mask layer pattern and the spacer.

In one example, the pull-back is carried out by dry etch. The hard mask layer is patterned using a high etch selection ratio, which exceeds a rate for stopping the corresponding etch at the silicon oxide layer for stress release, between the silicon oxide layer and the silicon nitride layer. According to one example, the high etch selection ratio may be 10:1. As a condition for dry etch to get the high etch selection ratio, HBr base gas is used at a temperature above 50° C.

When the spacer is formed, an etch amount is set up by considering a per-side amount according to the pull-back target.

This application claims the benefit of the Korean Application No. P2003-0100537 filed on Dec. 30, 2003, which is hereby incorporated by reference.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

1. An isolation method in a semiconductor device, comprising:
forming a hard mask layer by sequentially stacking a silicon oxide layer, a silicon nitride layer, and a thermal oxide layer on a semiconductor substrate;
forming a hard mask layer pattern by patterning the hard mask layer to expose a surface of the semiconductor substrate corresponding to a field area;
forming a spacer on each sidewall of the hard mask layer pattern by considering a per-side amount according to the pull-back target;
forming a trench in the semiconductor substrate by etching the exposed surface of the semiconductor substrate;
filling the trench with an insulating layer; and
removing the hard mask layer pattern and the spacer.

2. A method as defined by claim 1, wherein the pull-back is carried out by dry etch.

3. A method as defined by claim 1, wherein the hard mask layer is patterned using a high etch selection ratio, which exceeds a rate for stopping the corresponding etch at the silicon oxide layer for stress release, between the silicon oxide layer and the silicon nitride layer.

4. A method as defined by claim 3, wherein as a condition for dry etch to get the high etch selection ratio, HBr base gas is used at a temperature above 50° C.

5. The method of claim 1, wherein forming the spacer comprises an etch amount that is set up by considering a per-side amount according to the pull-back target.
